(19) United States
(12) Patent Application Publication
(10) Pub. No.: US 2010/0117279 A1
(43) Pub. Date: May 13, 2010

(54) SUPPORTING SYSTEM AND A METHOD FOR SUPPORTING AN OBJECT

(75) Inventors: Uri Vekstein, Haifa (IL); Valery Nuzni, Ma'alot (IL)

Correspondence Address: Pearl Cohen Zedek Latzer, LLP, 1500 Broadway, 12th Floor, New York, NY, 10036, US

(73) Assignee: CAMTEK LTD., Migdal-Haemek (IL)

(21) Appl. No.: 12/516,355

(22) PCT Filed: Nov. 25, 2007
(86) PCT No.: PCT/IL07/01453

§ 371 Date: Jan. 18, 2010

Related U.S. Application Data
(60) Provisional application No. 60/867,200, filed on Nov. 27, 2006.

(51) Int. Cl. H01L 21/683; B25B 11/00

(52) U.S. Cl. 269/21; 269/55

(57) ABSTRACT

A supporting system, the system includes a vertically movable chuck and a stationary chuck; wherein the vertically movable chuck and the stationary chuck are concentric; wherein the vertically movable chuck vertically moves between an upper position and a lower position; wherein when the vertically movable chuck is positioned at the upper position an upper surface of the vertically movable chuck is higher than an upper surface of the stationary chuck and when the vertically movable chuck is positioned at the lower position the upper surface of the vertically movable chuck is lower than the upper surface of the stationary chuck.

### FIELD OF THE INVENTION

The invention relates to a supporting system and to a method for supporting an object.

### BACKGROUND OF THE INVENTION

Many types of objects need to be supported by chucks. These objects include, for example, semiconductor wafers, glass objects and the like. Chucks are tailored to each type of object. Thus, glass supporting chucks differ from wafer supporting chucks. A typical inspection system can either inspect one type of object or include multiple spaced apart chucks, one chuck for each type of object.

There is a growing need to provide multiple purpose inspection systems that can inspect multiple types of objects. There is a growing need to reduce the space allocated for different chucks.

### SUMMARY OF THE INVENTION

A supporting system, the system includes a vertically movable chuck and a stationary chuck; wherein the vertically movable chuck and the stationary chuck are concentric; wherein the vertically movable chuck vertically moves between an upper position and a lower position; wherein when the vertically movable chuck is positioned at the upper position an upper surface of the vertically movable chuck is higher than an upper surface of the stationary chuck and when the vertically movable chuck is positioned at the lower position the upper surface of the vertically movable chuck is lower than the upper surface of the stationary chuck.

Conveniently the upper surface of the vertically movable chuck has a circular shape and a lower surface of the stationary chuck has a ring shape.

Conveniently a lower surface of the stationary chuck limits a vertical movement of the vertically movable chuck when the vertically movable chuck is positioned at the upper position.

Conveniently the stationary chuck defines an aperture that enables a supporting element to move through the aperture.

Conveniently the supporting system includes a background element adapted to be positioned on the vertically movable chuck.

Conveniently at least one vacuum channel is formed at an upper surface of the vertically movable chuck and wherein at least one vacuum channel is formed at an upper surface of the stationary chuck.

Conveniently the upper surface of the vertically movable chuck is smaller than an object to be supported by the vertically movable chuck and wherein an inner edge of the stationary chuck is shaped and sized such as to support the object.

Conveniently the supporting system includes an upper position pressure regulator and a lower position pressure regulator; wherein the upper position pressure regulator is adapted to regulate a fluid pressure provided to the vertically movable chuck such as to place the vertically movable chuck at the upper position; and wherein the lower position pressure regulator is adapted to regulate a fluid pressure provided to the vertically movable chuck such as to place the vertically movable chuck at the lower position.

Conveniently the supporting system includes calibration targets.

A method for supporting an object, the method includes: placing a vertically movable chuck at a lower position, placing the object on a stationary chuck and applying vacuum by the stationary chuck in response to a determination to support the object by the stationary chuck; placing the vertically movable chuck at a lower position, placing the object on the stationary chuck; moving the vertically movable chuck such as to contact the object; applying vacuum by the vertically movable chuck and moving the vertically movable chuck to an upper position in response to a determination to support the object by the vertically movable chuck; wherein the vertically movable chuck and the stationary chuck are concentric; wherein when the vertically movable chuck is positioned at the upper position an upper surface of the vertically movable chuck is higher than an upper surface of the stationary chuck and when the vertically movable chuck is positioned at the lower position the upper surface of the vertically movable chuck is lower than the upper surface of the stationary chuck.

Conveniently the upper surface of the vertically movable chuck has a circular shape and a lower surface of the stationary chuck has a ring shape.

Conveniently the method includes limiting a vertical movement of the vertically movable chuck by wherein a lower surface of the stationary chuck the vertically movable chuck is positioned at the upper position.

Conveniently the method includes receiving the object from a supporting element that moves within an aperture defined in the stationary chuck.

Conveniently the method includes placing a background element on the vertically movable chuck, in response to a determination to support the object by the stationary chuck.

Conveniently the method includes applying vacuum via at least one vacuum channel formed at an upper surface of the vertically movable chuck and applying vacuum via at least one vacuum channel formed at an upper surface of the stationary chuck.

Conveniently the method includes supporting the object by an inner edged of the stationary chuck; and supporting the object by the vertically movable chuck when positioned in the upper position; wherein the upper surface of the vertically movable chuck is smaller than the object.

Conveniently the method includes independently regulating a fluid pressure required for maintaining the vertically movable chuck at the lower position and fluid pressure required for maintaining the vertically movable chuck at the upper position.

### BRIEF DESCRIPTION OF THE DRAWINGS

The present invention will be understood and appreciated more fully from the following detailed description taken in conjunction with the drawings in which:

FIGS. 1, 2, 3 and 4 illustrate a supporting system according to an embodiment of the invention;

FIGS. 5, 6 and 7 illustrate a placement of a background element on a vertically movable chuck according to an embodiment of the invention;

FIGS. 8, 9, 10 and 11 illustrate a placement of an object on a stationary chuck by a supporting element according to an embodiment of the invention;

FIG. 12 illustrates an object that is supported by stationary chuck according to an embodiment of the invention;

FIGS. 13 and 14 illustrate a placement of a wafer on a vertically movable chuck according to an embodiment of the invention; and

FIG. 15 is a flow chart of a method for supporting an object according to an embodiment of the invention.

### DETAILED DESCRIPTION OF THE DRAWINGS

A multi-purpose supporting system is provided. It can effectively support multiple types of objects including transparent objects and non-transparent objects. By utilizing concentric chucks the overall area of the supporting system is reduced. Conveniently, both chucks participate in placement of objects on a vertically movable chuck.

It is noted that the various drawings are out of scale. In addition some drawings do not include all the features of the diced wafer adaptor, for simplicity of explanation.

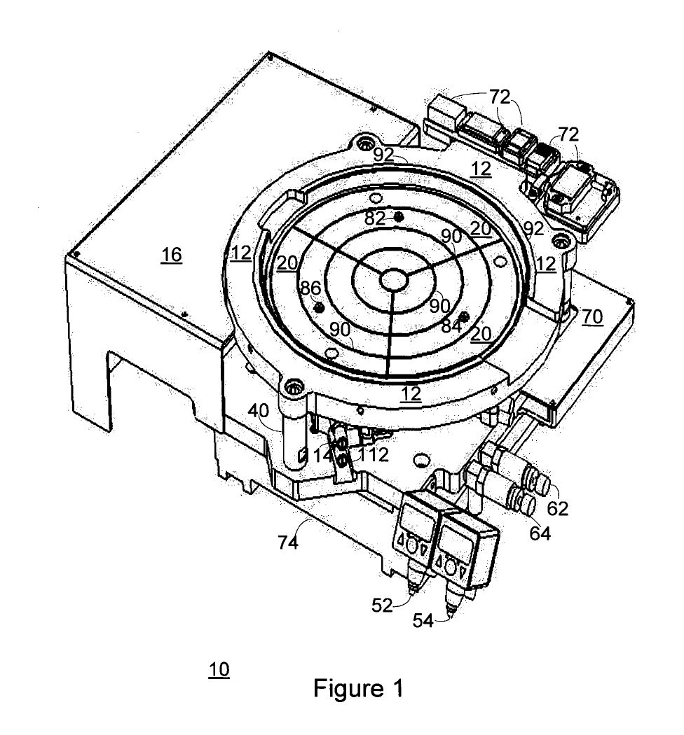

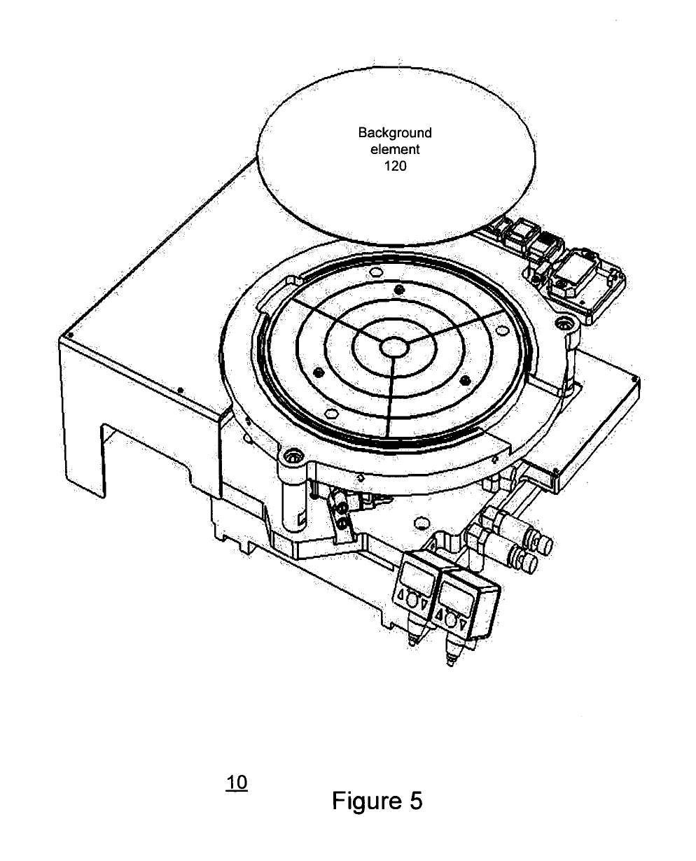

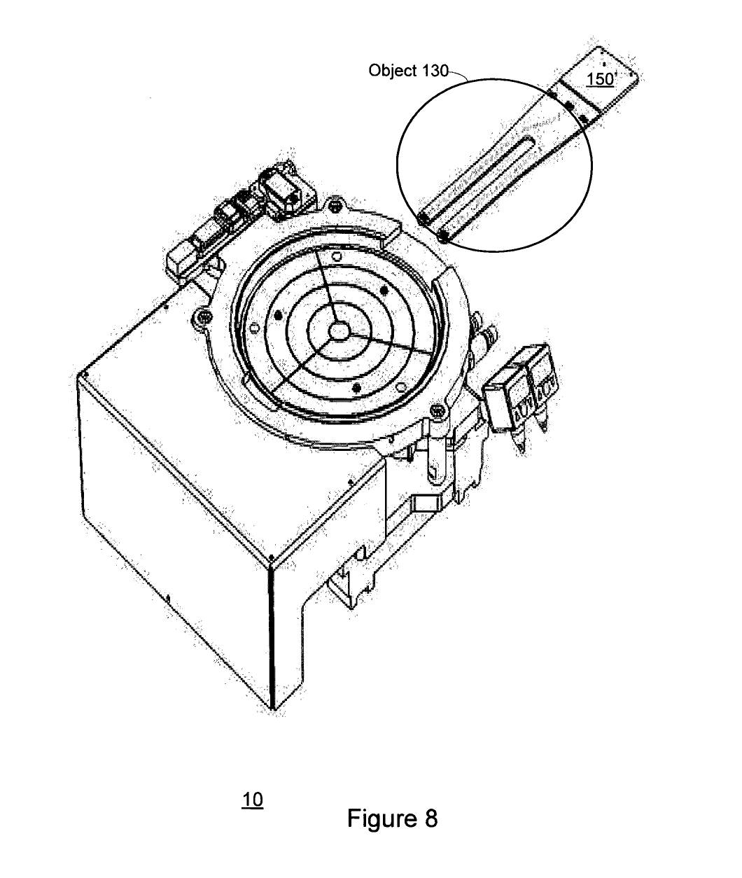

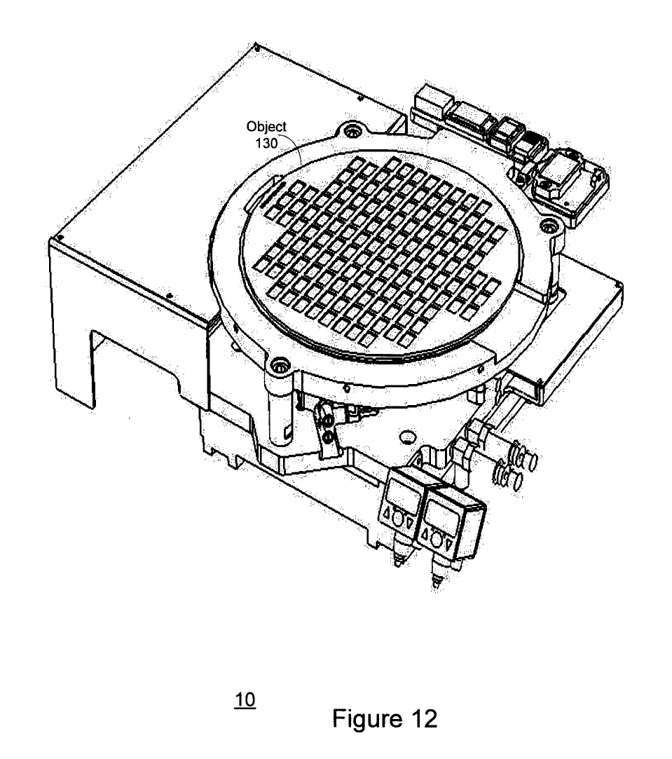

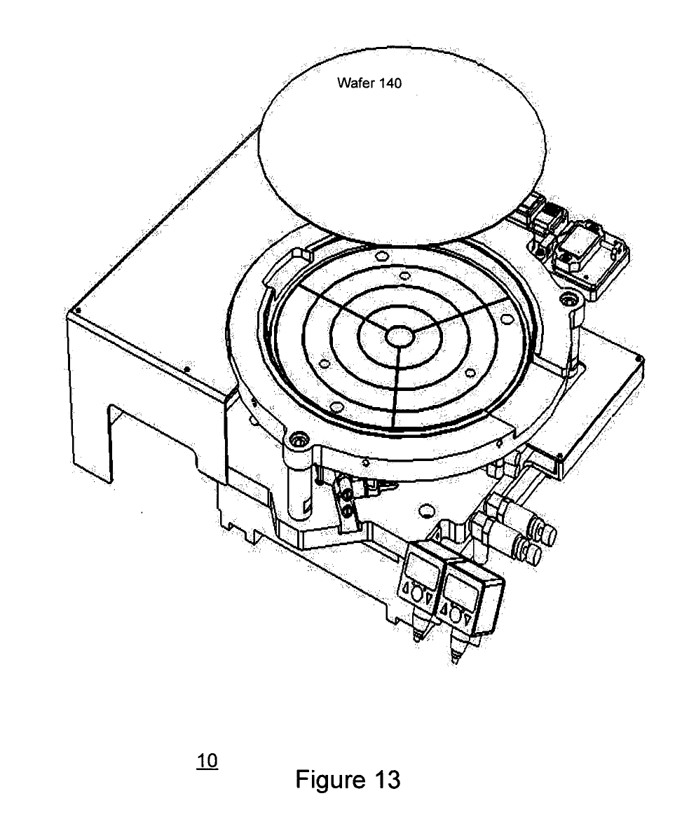

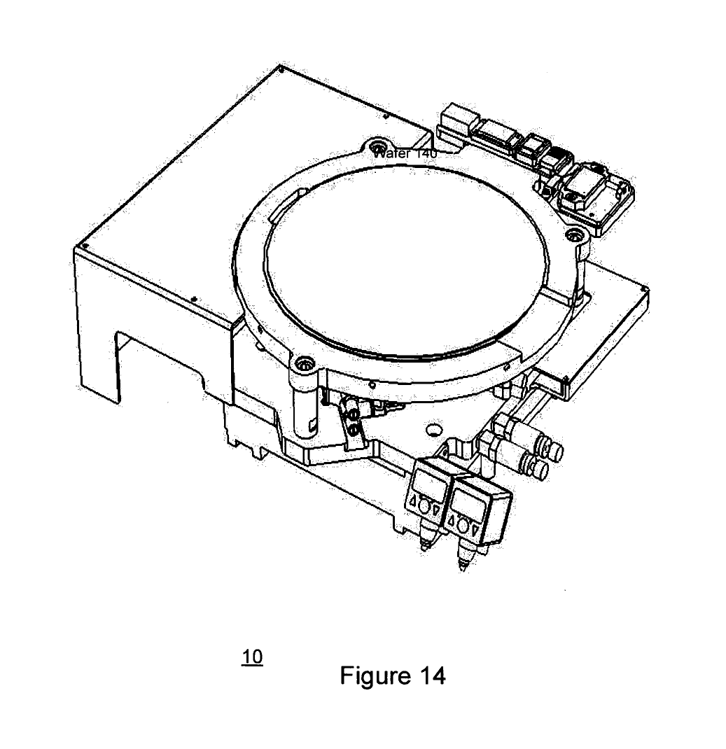

FIGS. 1, 2, 3 and 4 illustrate supporting system 10 according to an embodiment of the invention. FIGS. 5, 6 and 7 illustrate a placement of background element 120 on vertically movable chuck 20 according to an embodiment of the invention. FIGS. 8, 9, 10 and 11 illustrate a placement of object 130 on stationary chuck 12 by a supporting element such as end effector 150 according to an embodiment of the invention. FIG. 12 illustrates object 130 that is supported by stationary chuck 12 according to an embodiment of the invention. FIGS. 13 and 14 illustrate a placement of wafer 140 on vertically movable chuck 20 according to an embodiment of the invention.

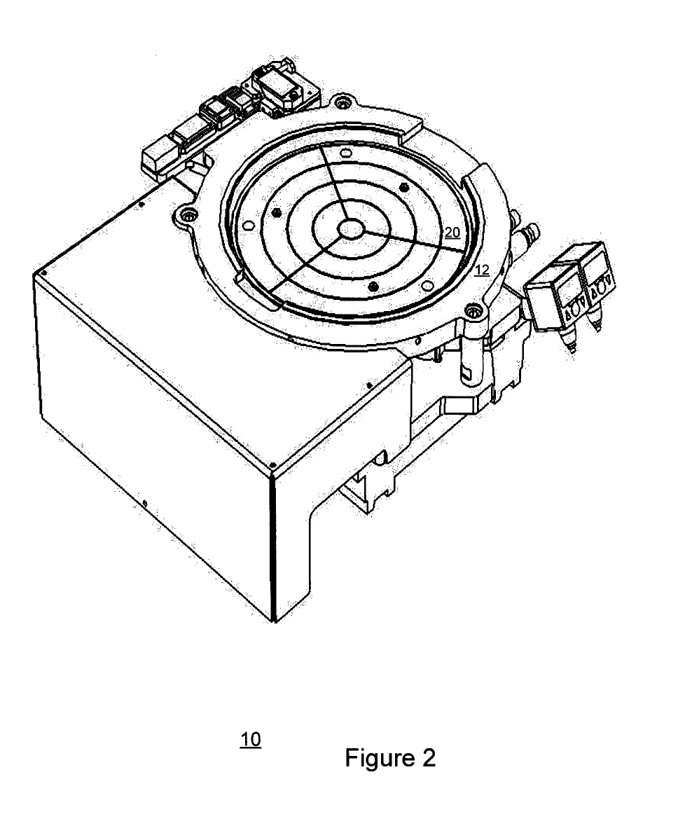

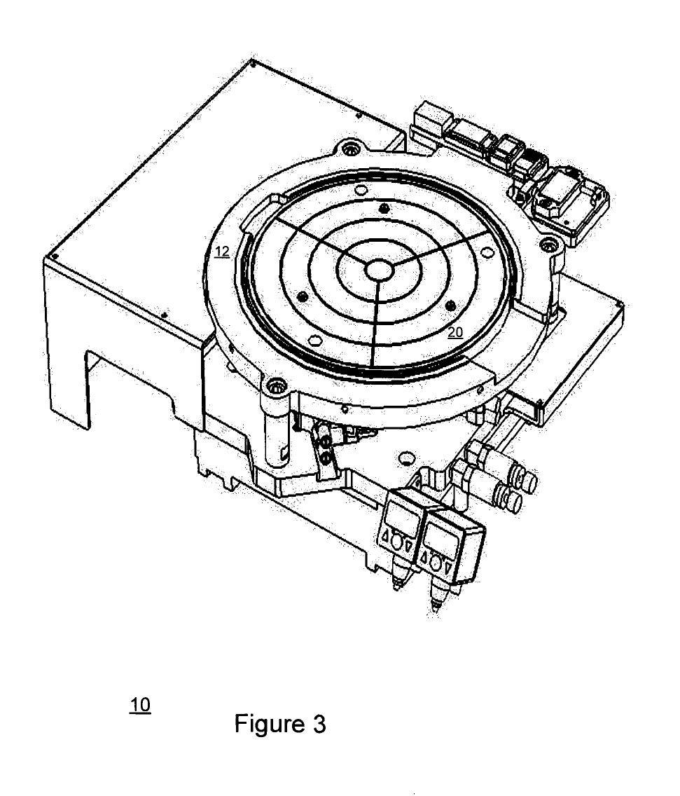

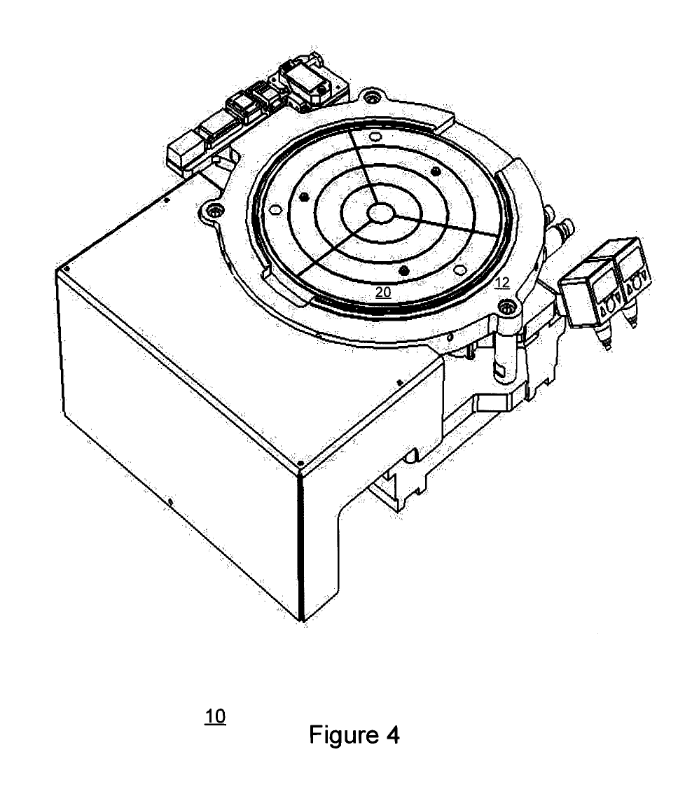

FIGS. 1 and 2 illustrates system 10 when vertically movable chuck 20 is positioned at a lower position while FIGS. 3 and 4 illustrate system 10 when vertically movable chuck 20 is positioned at an upper position.

Vertically movable chuck 20 and stationary chuck 12 are concentric. FIG. 1 illustrates a ring shaped stationary chuck 12 and a circular vertically movable chuck 20. It is noted that these chucks can have other shapes.

As illustrated in FIGS. 1, 2, 3 and 4, vertically movable chuck 20 can vertically moves between an upper position and a lower position. When vertically movable chuck 20 is positioned at the upper position an upper surface of vertically movable chuck 20 is higher than an upper surface of stationary chuck 12. When vertically movable chuck 20 is positioned at the lower position the upper surface of vertically movable chuck 20 is lower than the upper surface of stationary chuck 12. It is noted that vertically movable chuck 20 can be placed in one or more additional positions between the upper and lower positions, although this is not necessarily so.

Conveniently, vertically movable chuck 20 is placed in the upper position in a very accurate manner, by limiting it from exceeding a predefined height that is defined by stationary chuck 12. Conveniently, the lower surface of stationary chuck 12 limits a vertical movement of vertically movable chuck 20 when the vertically movable chuck 20 is positioned at the upper position.

The upper surface of vertically movable chuck 20 is smaller than an object to be supported by vertically movable chuck 30. An inner edge of the stationary chuck is shaped and sized such as to support such an object. Accordingly, an object (to be eventually provided to vertically movable chuck 20) is first supported by stationary chuck 20 and only after elevating vertically movable chuck 20 it is supported by vertically movable chuck 20.

In order to provide an object to either one of these chucks an object should be transferred from another location (not shown) that can be located at either side of these chucks. In order to simplify the provision of the object, aperture 30 is defined by stationary chuck 12. Through this aperture a supporting element (that supports the object before the object is supported by either one of the chucks) can move. The movement can include vertical movement and a horizontal movement. As will be further illustrated in FIGS. 8-11, aperture 30 simplifies the provision of an object to stationary chuck 12. It allows a placement of an object on stationary chuck 12 by using commonly used supporting elements that can place the object on stationary chuck 12 while supporting the lower surface of the object.

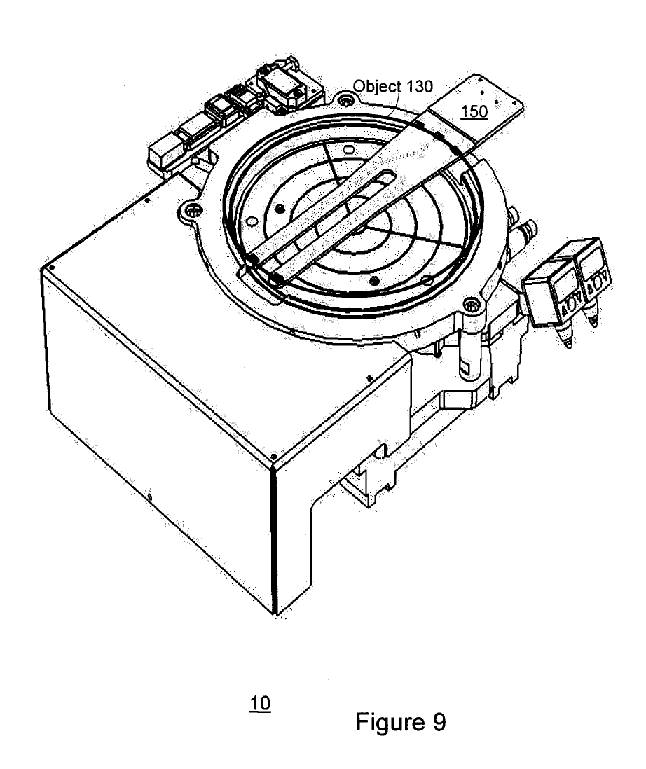

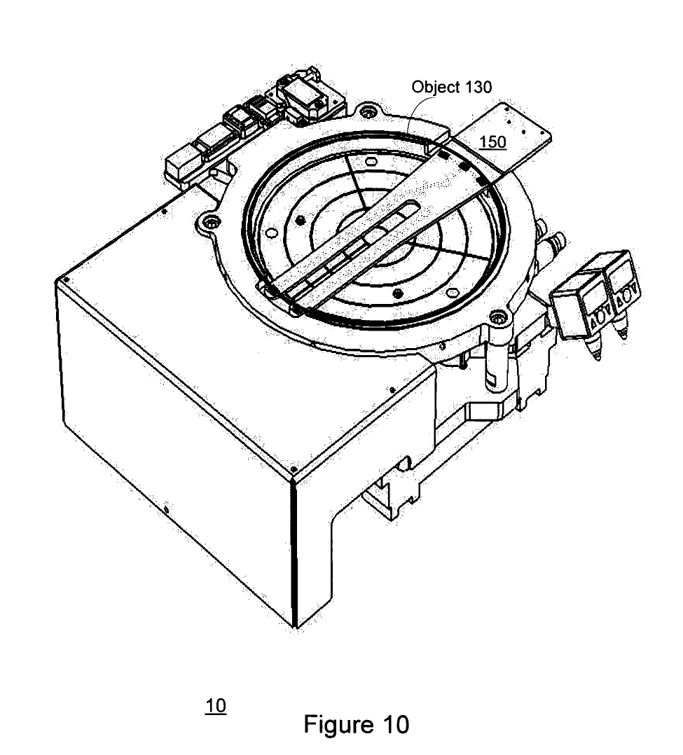

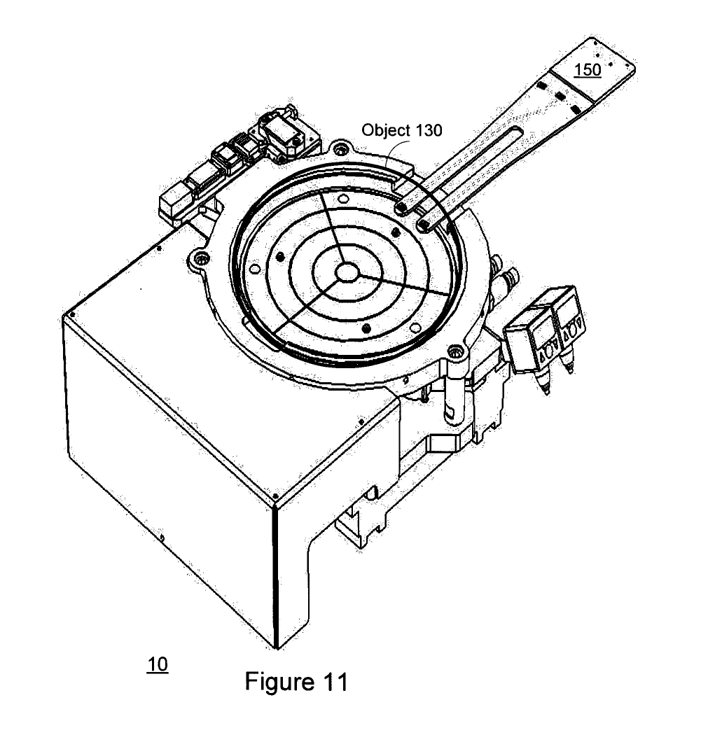

FIG. 8 illustrates supporting element 150 that approaches stationary chuck 12. Supporting element 150 supports object 130. FIG. 9 illustrates a forward and upper position of supporting element 150 after completing a horizontal movement through aperture 30. At this point supporting element contacts object 130. Object 130 can be placed on stationary chuck 12 but can be slightly above stationary chuck 12. Supporting element 150 is then lowered till it is positioned at a forward and lower position. During the lowering process object 130 can be placed on stationary chuck 12 (if it was not placed on stationary chuck 12 during the forward and upper position). FIG. 10 illustrates the forward and lower position of supporting element 150. At this point supporting element 150 does not contact object 130. Supporting element 150 is then moved away from stationary chuck 12. FIG. 11 illustrates a lower backward position of supporting element 150. At this point supporting element 150 is almost entirely out of aperture 30.

It is noted that when supporting element 150 removes object 130 from stationary chuck 130 the order of these mentioned above operations is reversed. For example, supporting element 150 is positioned at the lower backward position, is horizontally moved towards the forward and lower position, lifted to the forward and upper position (to contact object 130 and optionally to list it above stationary chuck 12) and then horizontally moved away from stationary chuck 12.

In some cases, and especially when an inspected object includes transparent or partially transparent areas, it is advantageously to have a certain background behind the object. This background can be fully reflective or fully observing (black) but this is not necessarily so as partially reflective backgrounds can also be required. According to an embodiment of the invention a background element having a desired optical characteristic is provided. This background element can be placed on vertically movable chuck 20 and places at a certain distance below an object that is supported by stationary chuck 12.

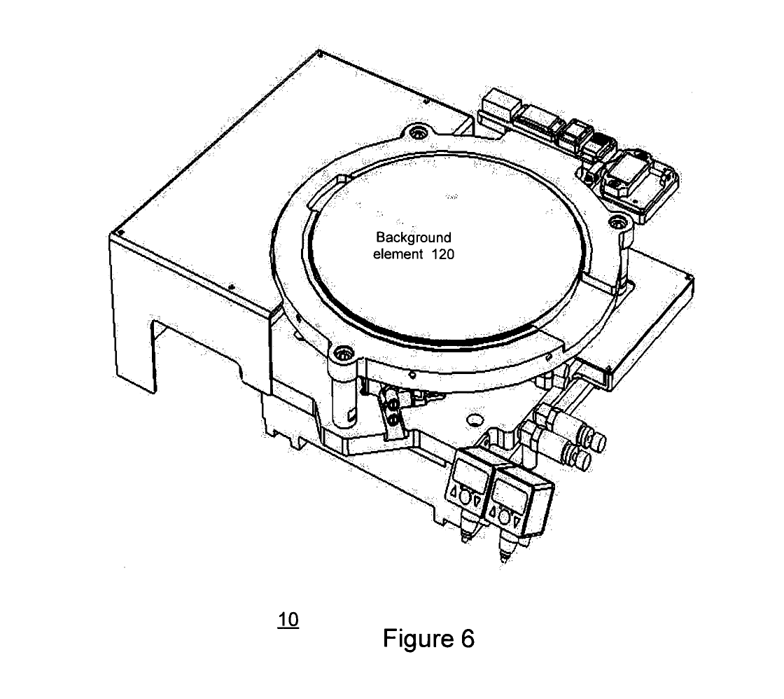

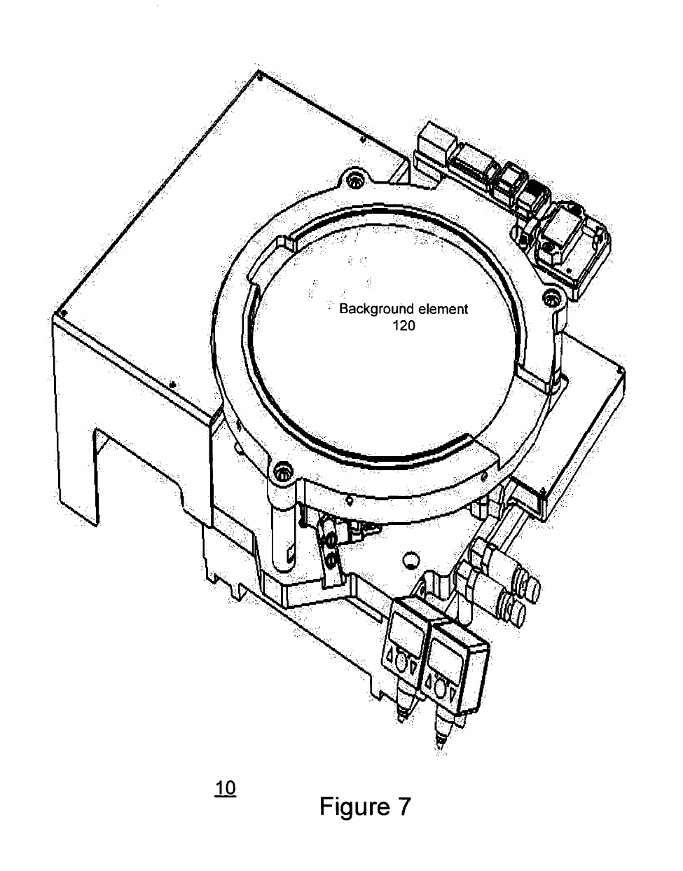

FIG. 5 illustrates a background element 120 and system 10. FIG. 6 illustrates a placement of background element 120 on vertically movable chuck 20 that is positioned at its upper position. FIG. 7 illustrates background element 120 on vertically movable chuck 20 after being lowered to its lower position. After this sequence of stages an inspected object can be placed on stationary chuck 12. The background element 120 is thin enough not to block aperture 30 and enable a placement of an object on stationary chuck 12 by supporting element 150, as illustrated in FIGS. 8-11.

Referring back to FIG. 1, multiple circular and radially extending vacuum channels 90 are formed at the upper surface of vertically movable chuck 20. Circular vacuum channel 92 is formed at an upper surface of stationary chuck 12. Three wafer anti-slide silicon caps 82, 84 and 86 are formed at the upper surface of stationary chuck 20. Stationary chuck 12 is connected to common base plate 70 via three posts such as post 40. The components (not shown) that support (and vertically move) vertically movable chuck 20 are also connected to common base plate 70. Flow metering valves 112 and 114 provide an indication about the fluid pressure that is provided to actuators of vertically movable chuck 20. Upper position pressure regulator 62 regulates a fluid pressure provided to vertically movable chuck 20 such as to place vertically movable chuck 20 at the upper position. Lower position pressure regulator 64 is adapted to regulate a fluid pressure provided to vertically movable chuck 20 such as to place vertically movable chuck 20 at the lower position. Vacuum sensors 52 and 54 sense the vacuum level at circular and radially extending vacuum channels 90 and at circular vacuum channel 92 respectively. Targets 72 are positioned in proximity to stationary chuck 12 such as to enable an inspection system to calibrate itself.

Conveniently supporting system 10 can be characterized by at least one of the following characteristics: (i) the upper surfaces of stationary chuck 12 and vertically movable chuck 20 are lapped to a flatness of about 5 microns (although other flatness levels can be maintained, (ii) the lower surface of stationary chuck 12 is also lapped to a flatness of few microns, (iii) when in upper position the upper surface of vertically movable chuck 20 is about half a Millimeter above the upper surface of stationary chuck 12, (iv) common base plate 70 is connected to a saddle 74 for an inspection linear motion stage; (v) a portion of stationary chuck 12 that extends few millimeters from the inner edge of stationary chuck 12 can support an object.

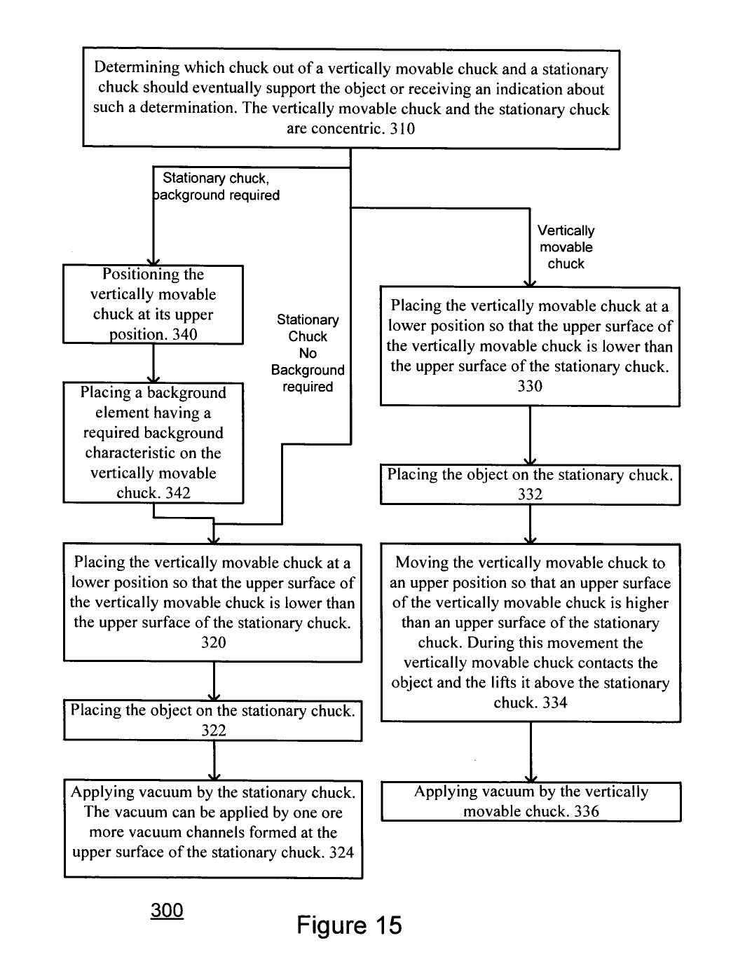

FIG. 15 illustrates method 300 for supporting an object, according to an embodiment of the invention.

It is assumed that stationary chuck 12 is used for supporting objects of certain types (such as glass or transparent objects) while vertically movable chuck 20 is used to support objects of other types (such as non-transparent objects and especially semiconductor wafers). Additionally or alternatively, stationary chuck 12 can support larger objects than vertically movable chuck 12, thus the determination can be responsive to the size of the object.

Method 300 starts by stage 310 of determining which chuck out of a vertically movable chuck and a stationary chuck should eventually support the object or receiving an indication about such a determination. The vertically movable chuck and the stationary chuck are concentric.

Referring to the example set fourth in FIG. 1, supporting system 10 is provided with an indication about the chuck that should eventually support the object.

If it is determined that the stationary chuck should eventually support the object and there is no need to place a background element below the inspected object (denoted “stationary chuck, not background required”) then stage 310 is followed by stages 320, 322 and 324.

Stage 320 includes placing a vertically movable chuck at a lower position so that the upper surface of the vertically movable chuck is lower than the upper surface of the stationary chuck. Stage 320 is followed by stage 322 of placing the object on a stationary chuck. Stage 322 is followed by stage 324 of applying vacuum by the stationary chuck. The vacuum can be applied by one ore more vacuum channels formed at the upper surface of the stationary chuck.

If it is determined that the vertically movable chuck should eventually support the object (denoted “vertically movable chuck”) then stage 310 is followed by stages 330, 332, 334 and 336.

Stage 330 includes placing the vertically movable chuck at a lower position so that the upper surface of the vertically movable chuck is lower than the upper surface of the stationary chuck. Stage 330 is followed by stage 332 of placing the object on a stationary chuck. Stage 332 is followed by stage 334 of moving the vertically movable chuck to an upper position so that an upper surface of the vertically movable chuck is higher than an upper surface of the stationary chuck. During this movement the vertically movable chuck contacts the object and the lifts it above the stationary chuck. Stage 334 is followed by stage 336 of applying vacuum by the vertically movable chuck. The vacuum can be applied by one ore more vacuum channels formed at the upper surface of the vertically movable chuck.

Conveniently, the upper surface of the vertically movable chuck has a circular shape and a lower surface of the stationary chuck has a ring shape.

Conveniently, stages 322 and 332 include receiving the object from a supporting element that moves within an aperture defined in the stationary chuck.

Conveniently, stage 336 includes limiting a vertical movement of the vertically movable chuck by the lower surface of the stationary chuck when the vertically movable chuck is positioned at the upper position.

Conveniently, stage 332 includes supporting the object by at least the inner edge of the stationary chuck and stage 338 includes supporting the object by an upper surface of the vertically movable chuck, wherein this upper surface is smaller than the object.

According to an embodiment of the invention, method 300 can also include stages 340 and 342. Stages 340 and 342 follow stage 310 if it is determined that the stationary chuck should eventually support the object and if it is determined that a background element is required (denoted “stationary chuck, background required”). Stage 340 includes positioning the vertically movable chuck at its upper position. Stage 340 is followed by stage 342 of placing a background element having a required background characteristic on the vertically movable chuck. Stage 342 is followed by stage 320.

Conveniently, stage 330 includes regulating a fluid pressure required for maintaining the vertically movable chuck at the lower position and stage 338 includes regulating a fluid pressure required for maintaining the vertically movable chuck at the upper position. These regulations are mutually independent.

Variations, modifications, and other implementations of what is described herein will occur to those of ordinary skill in the art without departing from the spirit and the scope of the invention as claimed. Accordingly, the invention is to be defined not by the preceding illustrative description but instead by the spirit and scope of the following claims.

We claim:

1. A supporting system, the system comprises a vertically movable chuck and a stationary chuck; wherein the vertically movable chuck and the stationary chuck are concentric; wherein the vertically movable chuck vertically moves between an upper position and a lower position; wherein when the vertically movable chuck is positioned at the upper position an upper surface of the vertically movable chuck is higher than an upper surface of the stationary chuck and when the vertically movable chuck is positioned at the lower position the upper surface of the vertically movable chuck is lower than the upper surface of the stationary chuck.

2. The supporting system according to claim 1 wherein the upper surface of the vertically movable chuck has a circular shape and a lower surface of the stationary chuck has a ring shape.

3. The supporting system according to claim 1 wherein a lower surface of the stationary chuck limits a vertical movement of the vertically movable chuck when the vertically movable chuck is positioned at the upper position.

4. The supporting system according to claim 1 wherein the stationary chuck defines an aperture that enables a supporting element to move through the aperture.

5. The supporting system according to claim 1 comprising a background element adapted to be positioned on the vertically movable chuck.

6. The supporting system according to claim 1 wherein at least one vacuum channel is formed at an upper surface of the vertically movable chuck and wherein at least one vacuum channel is formed at an upper surface of the stationary chuck.

7. The supporting system according to claim 1 wherein the upper surface of the vertically movable chuck is smaller than an object to be supported by the vertically movable chuck and wherein an inner edge of the stationary chuck is shaped and sized such as to support the object.

8. The supporting system according to claim 1 comprising an upper position pressure regulator and a lower position pressure regulator; wherein the upper position pressure regulator is adapted to regulate a fluid pressure provided to the vertically movable chuck such as to place the vertically movable chuck at the upper position; and wherein the lower position pressure regulator is adapted to regulate a fluid pressure provided to the vertically movable chuck such as to place the vertically movable chuck at the lower position.

9. The supporting system according to claim 1 further comprising calibration targets.

10. A method for supporting an object, the method comprises:
placing a vertically movable chuck at a lower position, placing the object on a stationary chuck and applying vacuum by the stationary chuck in response to a determination to support the object by the stationary chuck;
placing the vertically movable chuck at a lower position, placing the object on the stationary chuck; moving the vertically movable chuck such as to contact the object; applying vacuum by the vertically movable chuck and moving the vertically movable chuck to an upper position in response to a determination to support the object by the vertically movable chuck;
wherein the vertically movable chuck and the stationary chuck are concentric; wherein when the vertically movable chuck is positioned at the upper position an upper surface of the vertically movable chuck is higher than an upper surface of the stationary chuck and when the vertically movable chuck is positioned at the lower position the upper surface of the vertically movable chuck is lower than the upper surface of the stationary chuck.

11. The method according to claim 10 wherein the upper surface of the vertically movable chuck has a circular shape and a lower surface of the stationary chuck has a ring shape.

12. The method according to claim 10 comprising limiting a vertical movement of the vertically movable chuck by wherein a lower surface of the stationary chuck the vertically movable chuck is positioned at the upper position.

13. The method according to claim 10 comprising receiving the object from a supporting element that moves within an aperture defined in the stationary chuck.

14. The method according to claim 10 comprising placing a background element on the vertically movable chuck, in response to a determination to support the object by the stationary chuck

15. The method according to claim 10 comprising applying vacuum via at least one vacuum channel formed at an upper surface of the vertically movable chuck and applying vacuum via at least one vacuum channel formed at an upper surface of the stationary chuck.

16. The method according to claim 10 comprising supporting the object by an inner edged of the stationary chuck; and supporting the object by the vertically movable chuck when positioned in the upper position; wherein the upper surface of the vertically movable chuck is smaller than the object.

17. The method according to claim 10 comprising independently regulating a fluid pressure required for maintaining the vertically movable chuck at the lower position and fluid pressure required for maintaining the vertically movable chuck at the upper position.
